(19) United States
(12) Patent Application Publication
(10) Pub. No.: US 2023/0381929 A1
(43) Pub. Date: Nov. 30, 2023

(54) VACUUM SUBSTRATE CARRIER

(71) Applicant: CORNING INCORPORATED, CORNING, NY (US)

(72) Inventors: Hüseyin Umur, Munich (DE); Marco Andre Wolfert, Munich (DE)

(21) Appl. No.: 18/200,126

(22) Filed: May 22, 2023

Related U.S. Application Data
(60) Provisional application No. 63/346,572, filed on May 27, 2022.

(51) Int. Cl. B25B 11/00

(52) U.S. Cl. CPC B25B 11/005

(57) ABSTRACT

The present invention relates to a substrate carrier, comprising: a base plate (102) comprising a first area (104) and a second area (106); wherein the first area (104) comprises a first support surface (108) of the base plate (102) and the second area (106) comprises a recess (110) formed in the first support surface (108) of the base plate (102), wherein the first area (104) comprises an at least one first suction device (112) for providing vacuum force, and wherein the second area (106) comprises at least one second suction device (114) for providing vacuum force, wherein the at least one second suction device (114) comprises a second support surface (116) on the upper surface of the at least one second suction device, wherein the second support surface (116) is below the first support surface (108), and wherein the second support surface (116) comprises a sealing seating structure (118) surrounding a second suction opening (120).

### CROSS-REFERENCE TO RELATED APPLICATIONS

This application claims the benefit of priority under 35 U.S.C. § 119 of U.S. Provisional Application Ser. No. 63/346,572, filed on May 27, 2022, the content of which is relied upon and incorporated herein by reference in its entirety.

### FIELD

The present disclosure relates generally to apparatuses for holding substrates, and more particularly, to vacuum assisted apparatuses for holding substrates.

### BACKGROUND

Apparatuses for holding substrates can be used for a variety of applications. For example, an apparatus such as a substrate carrier are used to support and transport workpieces in a production area. For example, a substrate carrier can be used during laser processing processes to support, for example, a glass sheet while being irradiated by a laser beam. During laser processing, the workpiece is translated relative to the laser beam which can cause the workpiece to move.

Accordingly, the inventors have provided improved apparatus for holding substrates.

### SUMMARY

In a first embodiment, a substrate carrier, comprises: a base plate (102) comprising a first area (104) and a second area (106); wherein the first area (104) comprises a first support surface (108) of the base plate (102) and the second area (106) comprises a recess (110) formed in the first support surface (108) of the base plate (102), wherein the first area (104) comprises an at least one first suction device (112) for providing vacuum force, and wherein the second area (106) comprises at least one second suction device (114) for providing vacuum force, wherein the at least one second suction device (114) comprises a second support surface (116) on the upper surface of the at least one second suction device, wherein the second support surface (116) is below the first support surface (108), and wherein the second support surface (116) comprises a sealing seating structure (118) surrounding a second suction opening (120).

A second embodiment of the present disclosure may include the first embodiment, wherein the first support area is configured to support a first portion of a workpiece without one or more pre-formed functional parts and wherein the second area is configured to support a second portion of the workpiece having pre-formed functional parts.

A third embodiment of the present disclosure may include the second embodiment, wherein the at least one first suction device is configured to provide an area of low pressure between the first portion of the workpiece and the first support surface.

A fourth embodiment of the present disclosure may include any of the second to third embodiments, wherein the at least one second suction device is configured to provide an area of low pressure between the second portion of the workpiece and the second support surface.

A fifth embodiment of the present disclosure may include the first embodiment, wherein the base plate comprises a metal material.

A sixth embodiment of the present disclosure may include the first embodiment, wherein the base plate is integrally formed.

A seventh embodiment of the present disclosure may include the first embodiment, wherein the sealing seating structure comprises an elastic material.

An eighth embodiment of the present disclosure may include the seventh embodiment, wherein the elastic material is one of silicon or rubber.

A ninth embodiment of the present disclosure may include the seventh embodiment, wherein the sealing seating structure is one of a circular, a rectangular, or a pentagonal shape.

A tenth embodiment of the present disclosure may include the seventh embodiment, wherein the sealing seating structure has one of a circular cross-section, an elliptical cross-section, a rectangular cross-section, a solid cross-section or donut-shaped cross-section.

An eleventh embodiment of the present disclosure includes one of the previous embodiments, wherein the second suction device forms an integral part of the base plate.

A twelfth embodiment of the present disclosure includes one of the previous embodiments, wherein the first support surface is part of a third suction device.

A thirteenth embodiment of the present disclosure includes the twelfth embodiment, wherein the third suction device is formed as a protrusion at the base plate.

A fourteenth embodiment of the present disclosure includes one of the twelfth and thirteenth embodiments, wherein the third suction device comprises a third suction opening aligned with the first suction device.

### BRIEF DESCRIPTION OF THE DRAWINGS

The foregoing will be apparent from the following more particular description of example embodiments, as illustrated in the accompanying drawings in which like reference characters refer to the same parts throughout the different views. The drawings are not necessarily to scale, emphasis instead being placed upon illustrating the exemplary embodiments.

FIG. 1 depicts a schematic view of an apparatus for holding a workpiece in accordance with embodiments of the current disclosure.

### DETAILED DESCRIPTION

The present disclosure relates to apparatuses for holding substrates, and more particularly to vacuum assisted apparatuses for holding substrates, referred to herein as carriers, workpiece carriers, or substrate carriers. Embodiments of the current disclosure can be used, for example, during laser processing where the workpiece is translated relative to the laser beam and can advantageously prevent the workpiece from moving during processing. Additionally, embodiments of the current disclosure advantageously allow for processing (e.g. laser processing) of workpieces (e.g. glass sheets) having pre-formed functional parts (e.g. displays, partial coatings, electronic features).

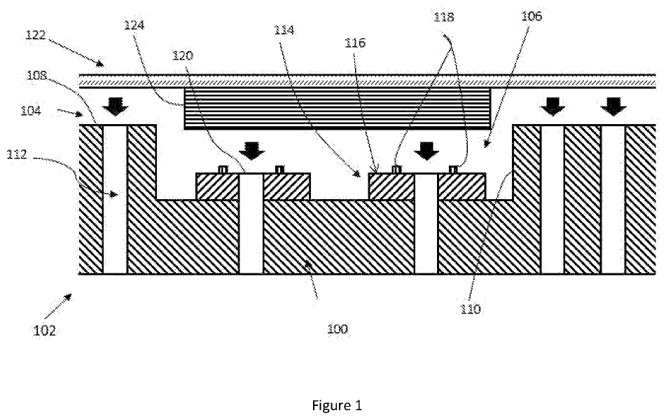

FIG. 1 depicts a schematic view of an apparatus for holding a workpiece in accordance with embodiments of the current disclosure. The substrate carrier 100 depicted in FIG. 1 comprises a baseplate 102. The baseplate 102 comprises a first area 104 and a second area 106. The first area 104 comprises a first support surface 108 of the base plate 102.

The first support surface 108 supports a workpiece 122, for example a glass substrate. In embodiments, the workpiece 122 comprises pre-formed functional parts 124 such as display features, partial coatings, and/or electronic features. The portion of the workpiece 122 without the pre-formed functional parts 124 is supported on the first support surface 108. The workpiece lays flat on the first support surface 108. The first area 104 comprises an at least one first suction device 112. The first suction device provides a vacuum force (i.e. forms a low pressure zone between the workpiece and the first support surface 108) to pull the workpiece 122 toward and hold the workpiece 122 on the first support surface 108.

The second area 106 comprises a recess 110 formed in the first support surface 108 of the base plate 102. The recess 110 accommodates the pre-formed functional parts 124 formed on the workpiece 122. The combination of the first support surface 108 and the recess 110 advantageously supports and holds the workpiece during laser processing without damaging the pre-formed functional parts 124 and also advantageously reduces the stress and/or tension on the workpiece from vibration of the laser processing machine.

The second area 106 further comprises at least one second suction device 114 within the recess 110. The second suction device 114 comprises a second support surface 116 on the upper surface of the second suction device 114. The second support surface 116 is within the recess 110 and positioned below the first support surface 108.

The second support surface 116 comprises a sealing seating structure 118 surrounding a second suction opening 120. The pre-formed functional parts 124 rest on the sealing seating structure 118 within the recess 110. The second suction opening 120 applies a vacuum force (i.e. forms a low pressure zone between the pre-formed functional parts 124 and the second support surface 116) to pull the pre-formed functional parts 124 toward and hold the pre-formed functional parts 124 on the sealing seating structure 118. The sealing seating structure 118 comprises an elastic material such as silicone or rubber. In embodiments, the elastic material may be a ring-like structure (e.g. O-ring). In another embodiment, the elastic material may be a coating or a film on the second support surface at least partially covering the second support surface. In embodiments, the elastic material is a vulcanized material, e.g. rubber. The elastic material may be arranged on the second support surface by any deposition process and/or using adherence. In embodiments, the elastic material is an integral part of the second suction device. Silicone as an elastic material has the advantage of high flexibility and heat resistance, as well as being free of imprints on other components to be attached to the elastic material, e.g. glass sheet. One example of silicon material has an elastic module preferably of <5 MPa and a heat resistance of up to 250° C. In embodiments, the sealing seating structure 118 may be coupled to the second support surface 116, for example via an adhesive. In embodiments, the second suction device 114 comprises at the second support surface 116 a recess to accommodate the sealing seating structure 118, which is press fit into the recess. In one embodiment the sealing seating structure 118 may be positioned in the recess. In embodiments, a combination of adhesive and recess may be used to couple the sealing seating structure 118 to the second support surface 116. In embodiments, the sealing seating structure 118 may be ring-shaped (e.g. an O-ring). In embodiments, the sealing seating structure 118 may have other suitable shapes such as rectangular or pentagonal. In embodiments, the sealing ring 118 may be of any cross-section, like circular, elliptical, rectangular, solid or with a hole inside. A sealing seating structure 118 of a circular shape has the advantage of high resistance against outer force when vacuum is applied because of uniform distribution of the outer force applied to the sealing seating structure and furthermore is easy to manufacture.

In embodiments, the base plate 102 is integrally formed (i.e. formed as a single unitary or monolithic piece) wherein the recess is formed by drilling or milling. In one embodiment the base plate 102 is manufactured by another method (e.g. 3d printing, sintering). In embodiments, the base plate is composed of and/or is made of a metal material, in particular a surface treated metal material. In embodiments, the base plate may be made aluminum, or steel, or plastic material. The advantage of a base plate made of aluminum is that it is easy to form, is light weight and low cost, and is resistant to laser light and environmental influences In embodiments, the base plate is formed of multiple components coupled together, for example, a flat lower base element comprising a first opening for a first suction device and a second opening for a second suction device, and an upper base element coupled to a top surface of the lower base element in the first area, wherein the portion of the base plate without the upper base element defines the second area of the base plate.

In embodiments, the second suction device forms an integral part of the base plate. This provides the advantage of manufacturing a precise base plate and precise position of the second area. Other advantages of the second suction device forming an integral part of the base plate is reduced time needed to position the second suction device and/or second area, reduced time for servicing and maintaining of the apparatus, and preventing incorrect positioning of second area and/or second suction device.

In embodiments, the first support surface is part of a third suction device which is formed as a protrusion at the base plate. In embodiments, the third suction device comprises a third suction opening aligned with the first suction device enabling modular placement of the first and/or third suction device.

While exemplary embodiments have been disclosed herein, it will be understood by those skilled in the art that various changes in form and details may be made therein without departing from the scope of the invention encompassed by the appended claims.

1. A substrate carrier, comprising:
a base plate (102) comprising a first area (104) and a second area (106);
wherein the first area (104) comprises a first support surface (108) of the base plate (102) and the second area (106) comprises a recess (110) formed in the first support surface (108) of the base plate (102),
wherein the first area (104) comprises an at least one first suction device (112) for providing vacuum force, and
wherein the second area (106) comprises at least one second suction device (114) for providing vacuum force, wherein the at least one second suction device (114) comprises a second support surface (116) on the upper surface of the at least one second suction device, wherein the second support surface (116) is below the first support surface (108), and wherein the second support surface (116) comprises a sealing seating structure (118) surrounding a second suction opening (120).

2. The substrate carrier of claim 1, wherein the first support area is configured to support a first portion of a workpiece without one or more pre-formed functional parts and wherein the second area is configured to support a second portion of the workpiece having pre-formed functional parts.

3. The substrate carrier of claim 2, wherein the at least one first suction device is configured to provide an area of low pressure between the first portion of the workpiece and the first support surface.

4. The substrate carrier of claim 2, wherein the at least one second suction device is configured to provide an area of low pressure between the second portion of the workpiece and the second support surface.

5. The substrate carrier of claim 1, wherein the base plate comprises a metal material.

6. The substrate carrier of claim 1, wherein the base plate is integrally formed.

7. The substrate carrier of claim 1, wherein the sealing seating structure comprises an elastic material.

8. The substrate carrier of claim 7, wherein the elastic material is one of silicone or rubber.

9. The substrate carrier of claim 7, wherein the sealing seating structure is one of a circular, a rectangular, or a pentagonal shape.

10. The substrate carrier of claim 7, wherein the sealing seating structure has one of a circular cross-section, an elliptical cross-section, a rectangular cross-section, a solid cross-section or donut-shaped cross-section.

11. The substrate carrier of claim 1, wherein the second suction device forms an integral part of the base plate.

12. The substrate carrier of claim 1, wherein the first support surface is part of a third suction device.

13. The substrate carrier of claim 12, wherein the third suction device is formed as a protrusion at the base plate.

14. The substrate carrier of claim 12, wherein the third suction device comprises a third suction opening aligned with the first suction device.
